(19) United States
(12) Patent Application Publication
(10) Pub. No.: US 2008/0149163 A1
(43) Pub. Date: Jun. 26, 2008

(54) SYSTEM AND METHOD FOR MOUNTING PHOTOVOLTAIC CELLS

(76) Inventor: Ron Gangemi, Nevada City, CA (US)

Correspondence Address: SHEPPARD, MULLIN, RICHTER & HAMPTON LLP, 333 SOUTH HOPE STREET, 48TH FLOOR, LOS ANGELES, CA, 90071-1448, US

(21) Appl. No.: 11/947,718

(22) Filed: Nov. 29, 2007

Related U.S. Application Data
(63) Continuation-in-part of application No. 10/931,183, filed on Aug. 31, 2004.

(51) Int. Cl. H01L 31/052; H01L 31/042; B29C 65/00

(52) U.S. Cl. 136/246; 136/251; 156/293

(57) ABSTRACT

The present invention is directed to a system for mounting photovoltaic cells on a surface, the system including a tile frame containing photovoltaic cells, an expansion arm on a side of the tile frame, a well in the expansion harm, and an adhesive in the well for contacting a cover. The invention is also directed to methods for making and using the system for mounting photovoltaic cells.

### REFERENCE TO RELATED APPLICATIONS

This application is a continuation-in-part of U.S. patent application Ser. No. 10/931,183, which was filed on Aug. 31, 2004, the content of which is incorporated herein by reference in its entirety.

### FIELD OF THE INVENTION

The present invention relates generally to photovoltaic cells. More particularly, the present invention relates to systems and methods for mounting photovoltaic cells.

### BACKGROUND OF THE INVENTION

A solar cell or photovoltaic (“PV”) cell is a device that converts light energy into electrical energy. The use of PV cells as an alternative to more expensive sources of energy has increased as power costs have increased. For example, some owners of commercial and residential buildings have used certain systems to install PV cells on the top of such buildings to reduce the building's overall dependence on energy provided by utility companies.

Systems for mounting PV cells generally, however, are difficult to install and fragile once they are installed. Additionally, to generate a significant amount of power, the system generally must include a large number of panels with PV cells, which can create wiring issues with respect to connections to the existing utility systems. Systems for mounting PV cells also tend to lack curb appeal.

### SUMMARY OF THE INVENTION

The present invention provides systems and methods for mounting tiles that contain PV cells. In one embodiment, the systems and methods of the present invention include an expression arm comprising an elongated member, wherein the elongated member includes a well configured to contain an adhesive. In another embodiment, the system comprises a first tile frame containing PV cells, an expansion arm on a side of the first tile frame, a well in the expansion arm and an adhesive in the well that is in contact with a protective cover (e.g., glass). It is generally preferred that the system also include a second tile frame, an opening in the second tile frame for receiving an expansion arm and a structure near the opening in the second tile frame to restrict the movement of the expansion arm in any direction other than in and/or out of the opening in the second tile frame. The first and second tile frames may be made out of a polymer.

The tile frames may include any suitable number of expansion arms, but preferably contain four expansion arms. The tile frames may also include a vent for cooling the PV cells, and preferably each tile frame includes three vents for cooling the PV cells. Additionally, the tile frames may include complementarily formed ends on the first and second tile frames that limit the movement of the expansion arms in and out of the openings in the tile frame and, thus, the distance between the first and second tile frames.

The present invention also provides methods for using the system to mount tiles that contain PV cells. In one embodiment, the method includes attaching a first tile frame to a surface, attaching a second tile frame to the first tile frame by inserting an expansion arm from either the first or the second tile frame into an opening in the other tile frame, adding an adhesive to a well in the expansion arm; and placing a cover in contact with the adhesive. Alternatively, the method includes attaching a first and second tile frames by inserting an expansion arm from either the first or the second tile frame into an opening in the other tile frame, attaching both tile frames to a surface, adding a flexible adhesive to a well in the expansion arm; and placing a cover in contact with the flexible adhesive, which allows the system to adjust to different surfaces without cracking or separating.

### BRIEF DESCRIPTION OF THE DRAWINGS

FIG. 1 illustrates an embodiment of a system according to the present invention.

FIG. 2 illustrates an embodiment of a system according to the present invention mounted on a surface.

FIG. 3 illustrates an embodiment of the frame interconnection shown in FIG. 2.

FIG. 4 illustrates an embodiment of a panel according to the present invention having ten PV cells.

FIG. 5 illustrates an embodiment of a panel according to the present invention having twelve PV cells.

FIG. 6 illustrates an embodiment of a panel according to the present invention having twenty-four PV cells.

FIG. 7 illustrates an embodiment of a frame according to the present invention.

FIG. 7A illustrates an embodiment of the fastener hole in the frame shown in FIG. 7.

FIG. 8 illustrates an embodiment of the present invention for attaching a wind loading clip.

FIG. 9 illustrates an embodiment of a wind loading clip according to the present invention.

FIG. 10 illustrates an embodiment of the present invention for attaching two frames using wind loading clips.

FIG. 11 illustrates an embodiment of the present invention for attaching two frames using wind loading clips.

FIG. 12 illustrates an embodiment of the present invention for attaching two frames using wind loading clips.

FIG. 13 illustrates an embodiment for a conversion and delivery system according to the present invention.

FIG. 14A illustrates an embodiment of a frame with expansion arms according to the present invention.

FIG. 14B illustrates an embodiment of a frame with expansion arms according to the present invention.

FIG. 15 illustrates an embodiment of a frame with expansion arms according to the present invention.

FIG. 16 illustrates an embodiment of a frame with openings for receiving expansion arms according to the present invention.

FIG. 17A illustrates an embodiment of a frame with openings for receiving expansion arms according to the present invention.

FIG. 17B illustrates a cross-section of a frame with openings for receiving expansion arms according to the present invention.

FIG. 18 illustrates an embodiment of the present invention for attaching two frames using expansion arms.

FIG. 19 illustrates an embodiment of a frame with complimentarily formed ends according to the present invention.

FIG. 20 illustrates an embodiment of a frame with a Z-shaped junction and Z-shaped lines according to the present invention.

### DETAILED DESCRIPTION

In the following paragraphs, the present invention will be described in detail by way of example with reference to the attached drawings. Throughout this description, the preferred embodiment and examples shown should be considered as exemplars, rather than as limitations on the present invention. As used herein, the “present invention” refers to any one of the embodiments of the invention described herein, and any equivalents. Furthermore, reference to various feature(s) of the “present invention” throughout this document does not mean that all claimed embodiments or methods must include the referenced feature(s).

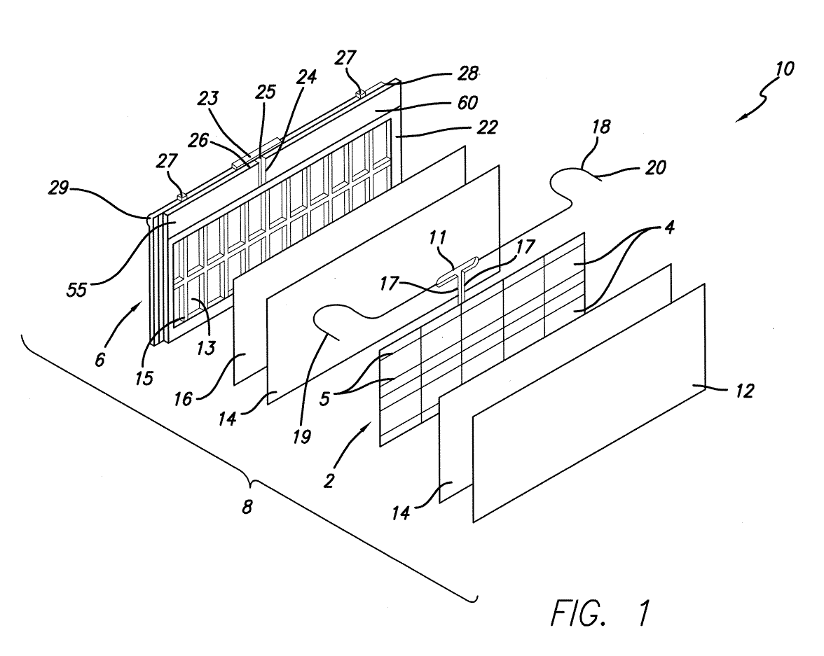

Referring now to the FIG.s, which are illustrative of multiple embodiments of the system of the present invention only and are not for purposes of limiting the same, FIG. 1 depicts a system 10 and tile 8 in accordance with one embodiment of the invention. The tile 8 includes a panel 2 of PV cells 4 for mounting in a frame 6. Tile 8 can contain any suitable number of PV cells 4, but it is generally preferred that each tile 8 include twelve PV cells 4. Additionally, the PV cells and/or the panel 2 can be any suitable size and the size of one or both can be increased/decreased in size so that the panel 2 can accommodate the desired number of PV cells 4. The PV cells may be electrically connected in any suitable manner, but it is generally preferred that the PV cells 4 are electrically connected in series to each other with each PV cell 4 having its own set of connection wires 5 to direct current away from the PV cells 4. The PV cells may also have a coating that maximizes energy production by providing enhanced absorption of available radiation.

As illustrated in FIG. 1, the tile 8 of the present invention is preferably constructed in layers. In one embodiment, the PV cells 4 are utilized in a panel 2, which provides a laminate support structure. In another embodiment, the panel 2 is made of a polymer with glass cuts that reduce the frame's expansion/contraction in response to temperature by raising the density of the polymer panel 2. The tile 8 may also contain a layer of ethyl-vinyl acetate 14 on either side of and adjacent to the PV cells 4, a glass outer sheet 12 adjacent the other side of one ethyl-vinyl layer 14, and an aluminum heat sink 16 adjacent the side remote from the glass outer sheet 12. Electrical tabs 17 extend from one edge of the panel 2 and are soldered onto a pair of electrical cables 18 having male and female connectors 19 and 20, respectively. The electrical cables 18 may be directed from the tabs 17 through an elongate U-shaped channel-like clip 11 for direction away from the panel 2.

The panel 2, as well as the layers of ethyl-vinyl acetate 14, the glass outer sheet 12 and the aluminum heat sink 16, nests in-whole or in-part within a frame 6. Thus, in one embodiment of the present invention, as illustrated in FIG. 1, the frame 6 has a recessed portion 22 to accept the panel 2. The recessed portion 22 contains windows 13 separated by spines 15. Although twenty-two windows 13 are illustrated in FIG. 1, the frame 6 may contain any suitable number of windows 13. The panel 2 is oriented in the frame 6 with the aluminum heat sink 16 contacting the recessed portion 22 of the frame 6, adjacent the window 13 and spine 15 area.

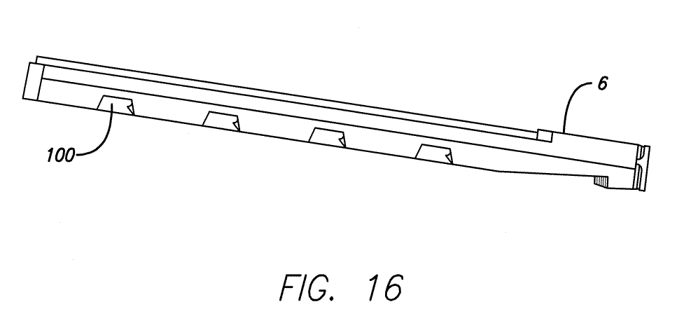

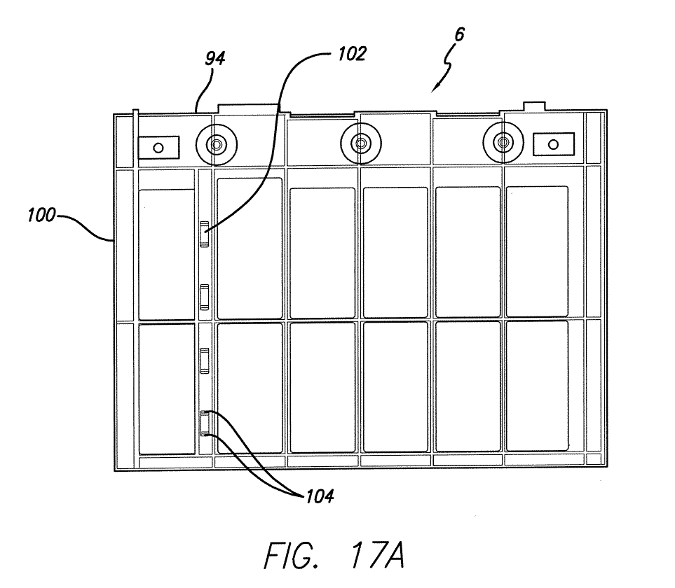

As illustrated in FIGS. 4A and 14B, the frame 6 can also include vents 110 in one or more sides of the frame 6 that promote convection or the transfer of heat away from the PV cells. The vents 110 can be of any suitable size for air to flow through the frame 6 and cool the PV cells. The vents 110 can also be any suitable shape, such as substantially rectangular as illustrated in FIGS. 4A and 14B. The frame 6 can also be of any suitable size, and preferably has a length of about 24 inches, a width of about 16 inches and a height of about 1 to 1.5 inches.

FIG. 1 further illustrates how the frame 6 may be attached to the panel 2 by a channel-like clip 11 on the panel 2 that is frictionally received and snapped into a hood 23 on the frame 6. The frame 6 may also include paths 24 that receive tabs 17 on the panel 2. Each of the tabs 17 has a separate path 24 and a separator 25 may be used to divide and hold the tabs 17 in spaced relation to prevent contact. A chaseway 26 may be used to accept and direct the electrical cables 18 from the panel 2 and the electrical cables 18 may be further directed through constraining clips 27 for correct orientation.

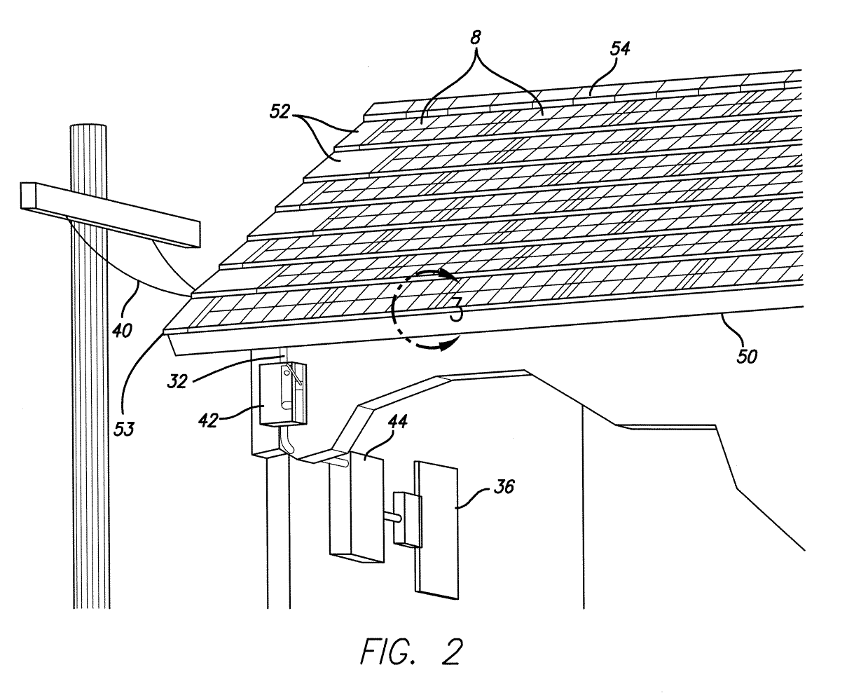

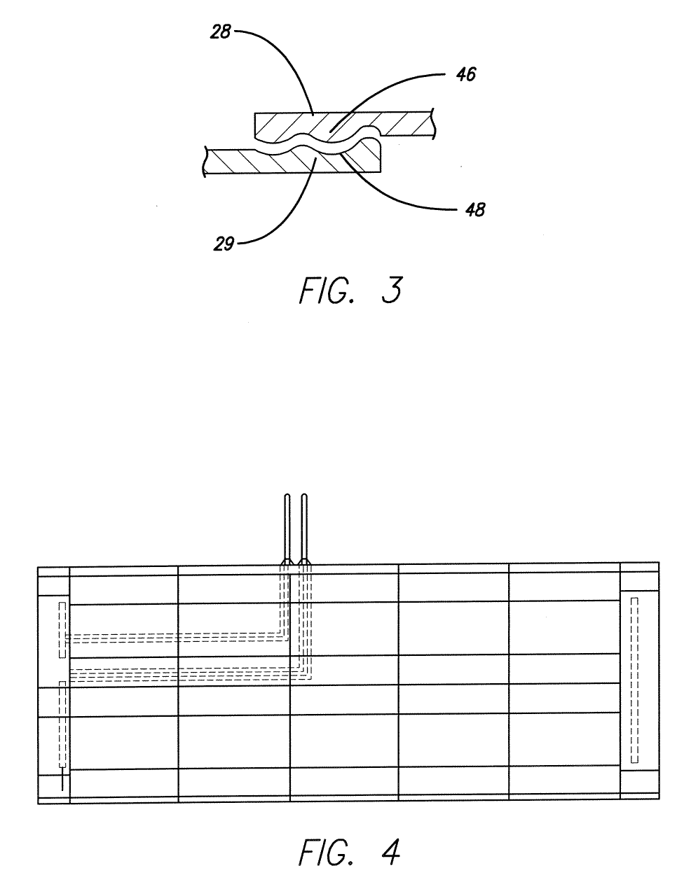

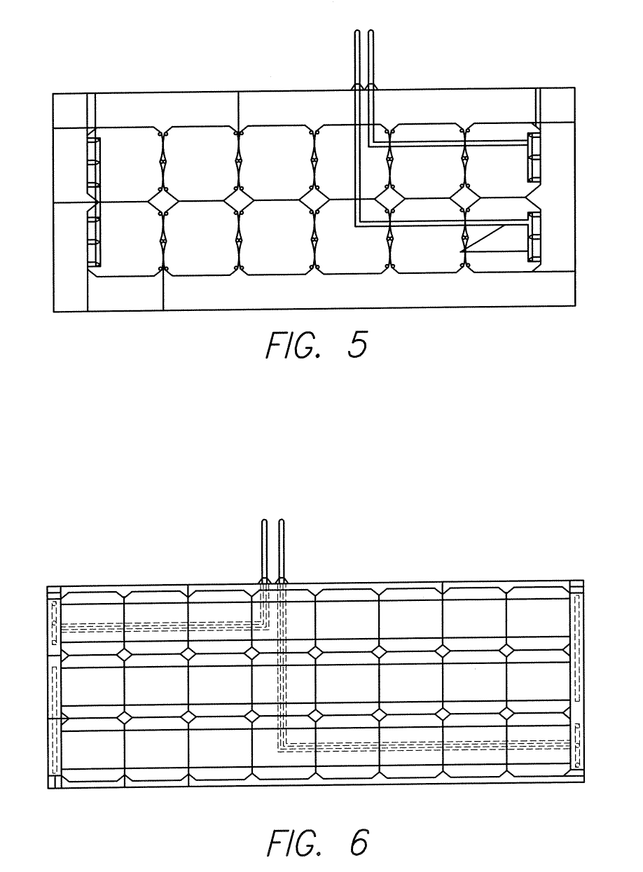

As illustrated in FIG. 2, one or more tiles 8 may be mounted on a surface 50, preferably a roof, where the PV cells 4 are exposed to actinic radiation. As illustrated in FIGS. 1, 3 and 19, the tiles 8 are equipped with complementarily formed ends 28 and 29 that allow adjacent tiles 8 to slide together. FIG. 3 illustrates how the tiles may also be joined together using a groove 46 and tongue 48 method. Additionally, as illustrated in FIGS. 14-18, adjacent tiles 8 may be slid together using one or more expansion arms 90, elongated members that extend from the end 92 of frame 6. The frame 6 may include any suitable number of expansion arms 90, such as four expansion arms 90 as illustrated in FIGS. 14-18. The expansion arms 90 may be any suitable length, and preferably are about 4.5 inches long.

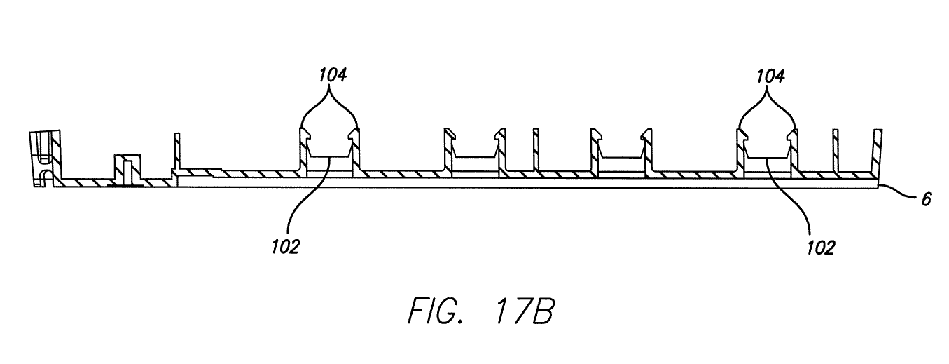

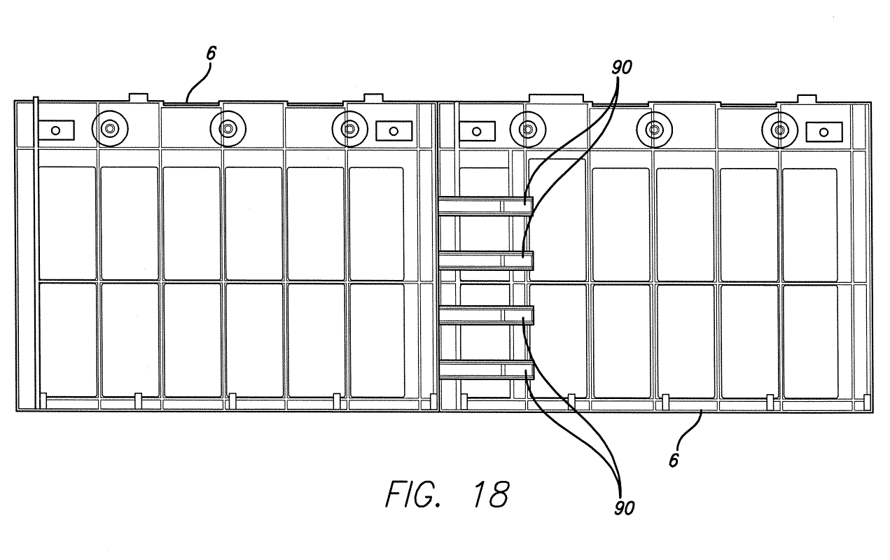

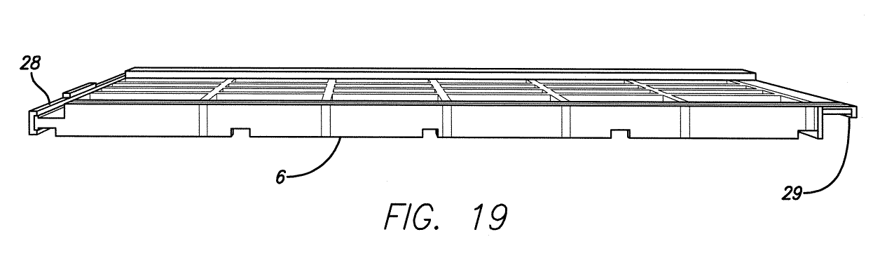

FIG. 18 illustrates multiple interconnected tiles 8 that were connected by advancing the expansion arms 90 through openings 100 and 102 in the end 94 of frame 6 on an adjacent tile 8. Each opening 100 and 102, as illustrated in FIGS. 16 and 17, is large enough to accommodate an expansion arm 90. The openings 100 and 102 are preferably in a shape complementary to the shape of the expansion arm 90, but may be any suitable shape or configuration to receive the expansion arm 90. It is preferred that the openings 100 and 102 contain a suitable structure to prevent the expansion arm 90 from moving in any direction other than in and out of openings 100 and 102. For example, openings 100 and 102 can be in the shape of a square tube. Alternatively, as illustrated in FIGS. 17 and 18, openings 100 and 102 can be in the shape of a square tube with one side removed and a clip 104 or other means of engagement included in opening 102 that engages expansion arm 90, preventing the expansion arm 90 from moving in any direction other than in and out of openings 100 and 102.

The tightness of the fit between expansion arm 90 and openings 100 and 102 (and/or clips 104) may be adjusted as desired, but it is generally preferred that the fit is not so tight as to prevent the expansion arms 90 from sliding in and out of openings 100 and 102. This enables the tiles 8 to adjust as necessary in response to expansion or contraction due to weather conditions, characteristics of and/or changes to surfaces 50 where the tiles 8 are mounted and other factors affecting the mounting of the tiles 8. The amount of adjustment, i.e., the ability of one tile 8 to move with respect to an adjacent tile 8, may be limited by complementarily formed end 28 on one tile 8, which acts as a stop by catching complementarily formed end 29 (See FIGS. 14A and 19) on the adjacent tile 8. The amount of adjustment allowed before the complementarily formed ends 28 and 29 engage each other, preventing further separation between adjacent tiles 8, can be any suitable distance, and preferably is about 0.5 inches.

As illustrated in FIGS. 14B and 15, the expansion arms 90 are configured to include a well 96, which can hold an adhesive. Although any suitable adhesive can be used, the adhesive is preferably a type of polycarbonate or a Noryl resin, which is manufactured by GE Plastics. A protective cover, such as glass 12, or other parts of the tile 8 can be placed in contact with the adhesive, which is flexible enough for certain parts to accept more or less weight than others and thereby adjusts to different surfaces 50 without cracking or separating.

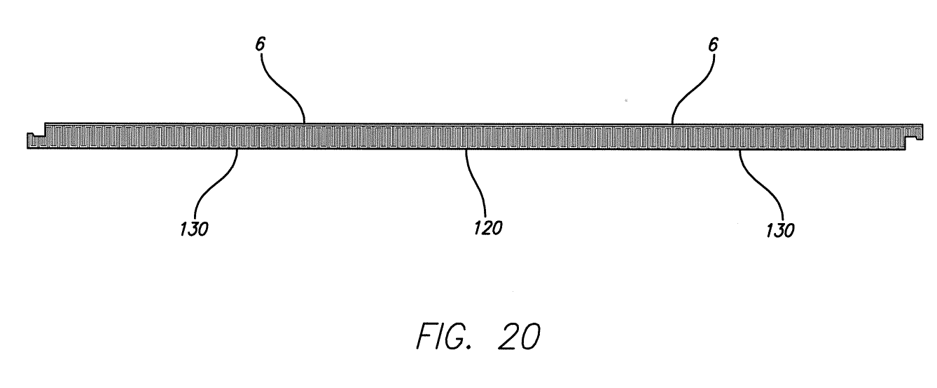

When two or more tiles 8 are connected by advancing the expansion arms 90 through the openings 100 and 102 and mounted on a surface 50, the tiles are generally mounted with a predetermined amount of space between the tiles 8. Preferably, the amount of space between the surface 112 on the one tile 8 and the complementarily formed end 29 on the adjacent tile 8 is approximately 0.125 inches. Likewise, it is preferred that the amount of space between the surface 114 on the one tile 8 and the complementarily formed end 28 on the adjacent tile 8 is approximately 0.125 inches. Also, as illustrated in FIG. 20, when two tiles 8 are mounted and connected together, the tiles 8 form a substantially Z-shaped junction 120 when viewed from the side. According to some embodiments of the invention, the tiles 8 may also include substantially Z-shaped lines 130 that gives the appearance of a junction. These lines 130 are simply molded into the frame 6 instead of being actual Z-shaped junctions 120. Such lines 130 may be employed to create the appearance of multiple tiles 8 within a single tile 8.

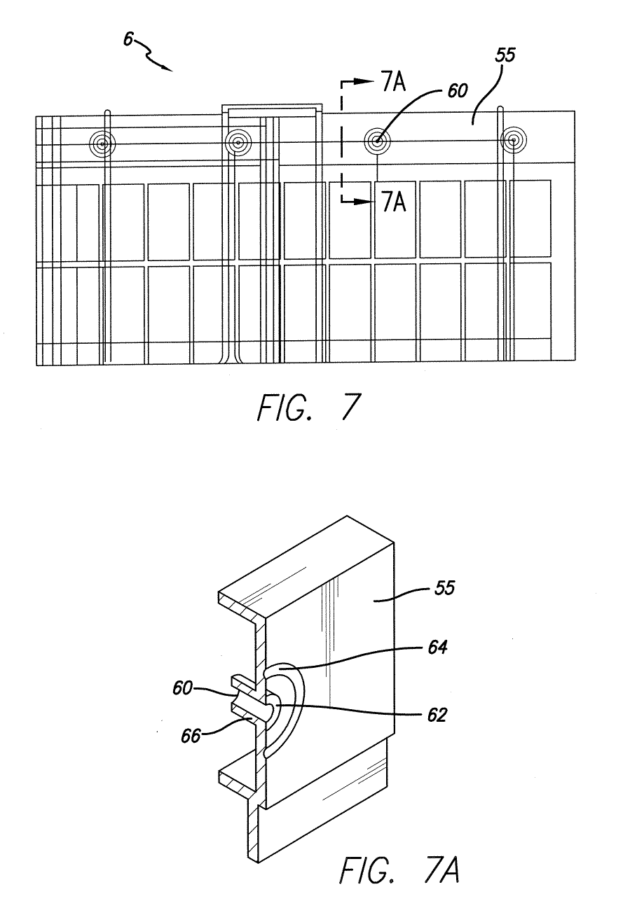

Referring to FIGS. 7A and 7B, a plurality of circular fastener holes 60, preferably four, are located on the windowless portion 55 of the frame 6. Each hole 60 is preferably circumscribed by a plurality of concentric grooved portions 62 and 64 alternating with a ringed portion 68, with the fastener hole 60 located at the lowest central point therein. The grooved portions 62 and 64 are grooves relative to the plane of the surface of the windowless portion 55 of the frame 6. In other words, the grooves are recessed into the frame 6. The hole 60 is first circumscribed by a chamfered edge 66 and then by a first groove 62. A ringed portion 68 circumscribes the first groove 62. The top of the ringed portion 68 is in the same plane as the surface of the windowless portion 55 of the frame 6. A second groove 64 circumscribes the ringed portion 68. The second groove 64 is preferably recessed an identical amount as the first groove 62.

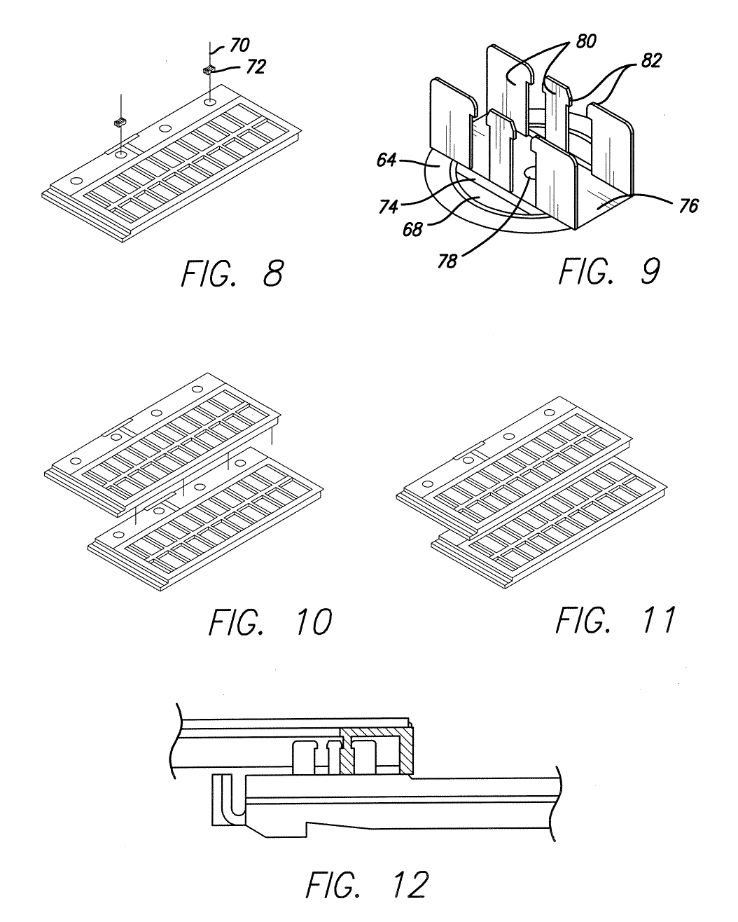

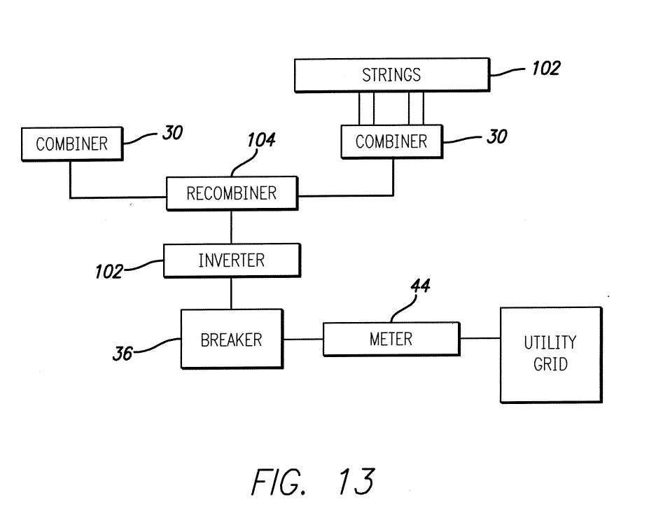

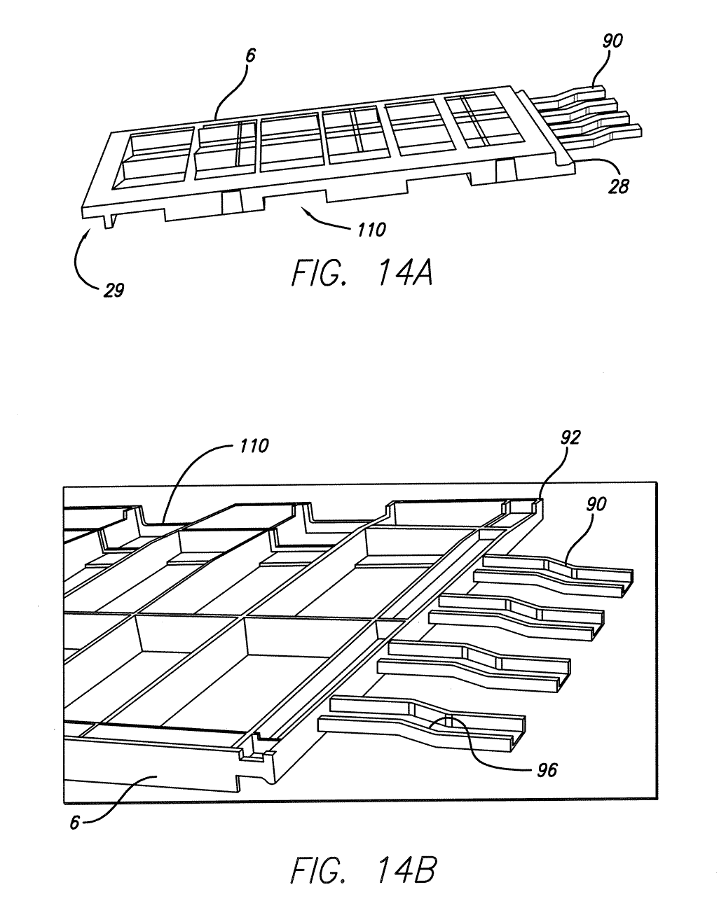

Referring to FIG. 8, the holes 60 receive mounting screws 70 and can also secure optional wind loading clips 72. Anti-rotational ribs 74 are located on the portion 55 of the frame 6 on either side of the wind loading clips 72, as shown in FIG. 9, to help locate the clips 72 on the frame 6. The wind loading clips 72 have a planar, preferably rectangular, bottom portion 76 and a centrally located screwbore 78. The screwbore is placed directly over the hole 60, and the bottom portion 76 rests across the circumscribing grooves 62 and 64 and ringed portion 68, located by the ribs 74. From the bottom portion 76, the wind loading clip 72 extends upwardly on either side along the long axis to form teeth 80. Each of the teeth 80 has endprongs 82 that allow multiple frames 6 to be interlocked with one another (See FIGS. 10, 11 and 12). This interlocking produces an offset, overlapping shingle-type array.

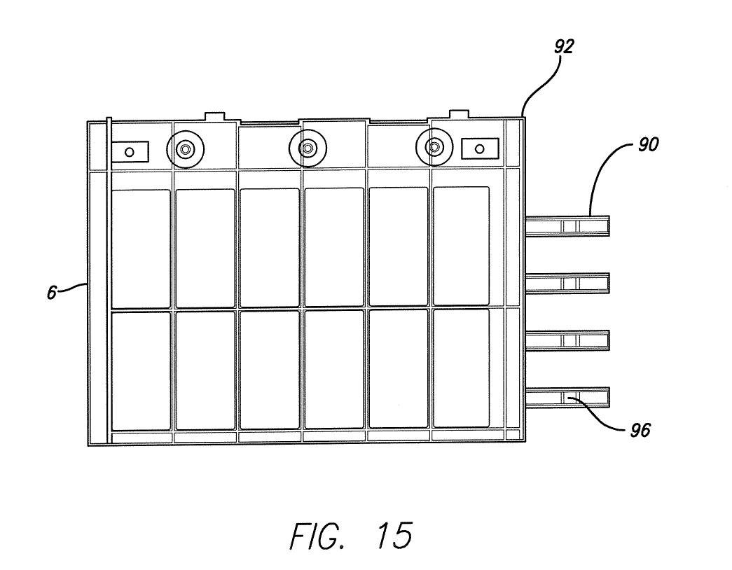

In one embodiment, as illustrated in FIG. 9, the wind loading clip 72 can be rotated 90 degrees about the mounting screw 70 to permit joining of additional tiles 8, whether such additional tiles 8 are oriented in the vertical or horizontal orientation. The anti-rotational ribs 74 are formed on either side of each wind loading clip 72 on portion 55, utilizing the grooves 62 and 64 and ringed portion 68, to selectively prevent the wind loading clips 72 from moving. Specifically, rotational movement of the wind loading clip 72 about the mounting screw 70 is prevented to ensure a stable structure when frames 6 are joined together and held by the end prongs 82, as shown in FIG. 12.

The PV cells 4 can be aesthetically color coordinated with the building and exhibit a range of pigmentation while still capturing as much radiation from the available spectrum of light as possible. Specifically, the PV cells 4 typically exhibit blue or gray color, using conventional photocells, which has been shown to provide efficient conversion of the full range of radiation. In addition, however, the tiles 8 may exhibit a red color by using pink colored glass 12, which maintains efficient conversion of radiation.

Several tiles 8, for example eleven, are connected in series with one another via male and female connectors 19 and 20 to form a string of tiles 8. Strings of tiles 8 are mounted on the surface 50, preferably a roof. At the edge of the surface 50, an edge piece 52 is placed, then a string of tiles 8. The edge pieces 52 are available in different widths to produce patterns of tiles 8 that are offset from one another, as shown in FIG. 2. The end of the edge piece 52 that engages the tile 8 is equipped with the same type of sliding end 28 and 29 as the tiles 8. The remote end 53 of the edge piece 52 may end flush with the edge of the surface 50, or it may exhibit an overhang relative to the edge of the surface 50. Peaked portions of a surface 50 are covered with cap blocks 54. The cap blocks 54 are capable of connecting to the tiles 8 or to the surface 50 itself.

As shown in FIG. 3, the sliding ends 28 and 29 on each tile 8 allow physical interconnection of the tiles 8 that are electrically connected with one another. Each string of tiles 8 has its own pair of wires that pass through the subroof to the attic below (See FIG. 13). This pair of wires terminates in a combiner box 30 that combines the wires from each string of tiles 8 into a single pair of wires 32, preferably larger copper wires. Several combiner boxes 30 may be used in system 10. A recombiner 104 is used to join multiple combiner boxes such that a single pair of wires 32 carries the power that originates in the cells 4.

For systems 10 connected to a utility power line 40, synchronous inverters 42 are used to produce AC power in synchronization with the power line. The inverter produces power that is of a quality acceptable to the utility company. In these systems 10, the utility company serves as the primary energy storage medium. One side of the synchronous inverter 42 is connected to the DC power, and the other is connected through a meter 44 to a circuit breaker box 36 (See FIG. 2).

This connection method allows the utility company to measure the amount of power generated. In systems with only one meter 44, the meter runs backward as energy is produced and excess power is fed into the utility lines 40. When the system 10 generates electricity, the inverter 42 supplies power to meet usage. When usage exceeds production of the system 10, excess power from the utility company is drawn from the utility line 40.

Some systems 10 may incorporate a battery 108 for emergency power or for storage of excess power produced. In addition, a stand-alone inverter or an inverter that operates as a stand-alone inverter or a utility-interactive inverter may be utilized in the system.

The number of cells 4 in the panel 2 determines the output of the tile. A panel of ten 6″-by-6″ cells produces 28 watts at about 5 volts, a panel of twelve 5″-by-5″ cells produces 35 watts at about 7 volts, and a panel of twenty-four 4″-by-4″ cells produces 36 watts at about 12 volts.

Thus, it is seen that devices and methods for making, mounting and using PV cells are provided. One skilled in the art will appreciate that the present invention can be practiced by other than the various embodiments and preferred embodiments, which are presented in this description for purposes of illustration and not of limitation, and the present invention is limited only by the claims that follow. It is noted that equivalents for the particular embodiments discussed in this description may practice the invention as well.

While various embodiments of the present invention have been described above, it should be understood that they have been presented by way of example only, and not of limitation. Likewise, the various diagrams may depict an example architectural or other configuration for the invention, which is done to aid in understanding the features and functionality that may be included in the invention. The invention is not restricted to the illustrated example architectures or configurations, but the desired features may be implemented using a variety of alternative architectures and configurations. Indeed, it will be apparent to one of skill in the art how alternative embodiments may be implemented to achieve the desired features of the present invention. Also, a multitude of different constituent part names other than those depicted herein may be applied to the various parts of the invention. Additionally, with regard to operational descriptions and method claims, the order in which the steps are presented herein shall not mandate that various embodiments be implemented to perform the recited functionality in the same order unless the context dictates otherwise.

Although the invention is described above in terms of various exemplary embodiments and implementations, it should be understood that the various features, aspects and functionality described in one or more of the individual embodiments are not limited in their applicability to the particular embodiment with which they are described, but instead may be applied, alone or in various combinations, to one or more of the other embodiments of the invention, whether or not such embodiments are described and whether or not such features are presented as being a part of a described embodiment. Thus the breadth and scope of the present invention should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

A group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise. Furthermore, although items, elements or components of the invention may be described or claimed in the singular, the plural is contemplated to be within the scope thereof unless limitation to the singular is explicitly stated.

The presence of broadening words and phrases such as “one or more,” “at least,” “but not limited to” or other like phrases in some instances shall not be read to mean that the narrower case is intended or required in instances where such broadening phrases may be absent.

1. A system for mounting tiles that contain photovoltaic cells comprising:
a first tile frame containing photovoltaic cells;
an expansion arm on a side of the first tile frame;
a well in the expansion arm; and
an adhesive in the well.

2. The system of claim 1 further comprising:
a second tile frame;
an opening in the second tile frame for receiving the expansion arm; and
a structure near the opening in the second tile frame to restrict the movement of an expansion arm other than movement in and out of the opening in the second tile frame.

3. The system of claim 1, wherein the first tile frame is polymer.

4. The system of claim 1, wherein first tile frame contains four expansion arms.

5. The system of claim 1, wherein the adhesive is flexible.

6. The system of claim 1 further comprising a vent in the first tile frame for cooling the photovoltaic cells.

7. The system of claim 6, wherein the first tile frame contains three vents for cooling the photovoltaic cells.

8. The system of claim 1 further comprising a Z-shaped line in the tile frame.

9. The system of claim 2 further comprising complementarily formed ends on the first and second tile frames.

10. A method for mounting tiles that contain photovoltaic cells comprising:
attaching a first tile frame to a surface;
attaching a second tile frame to the first tile frame by inserting an expansion arm from either the first or the second tile frame into an opening in the other tile frame;
adding an adhesive to a well in the expansion arm; and
placing a cover in contact with the adhesive.

11. The method of claim 10, wherein the first tile frame is a polymer.

12. The method of claim 10, wherein a tile frame contains four expansion arms.

13. The method of claim 10, wherein the adhesive is flexible.

14. The method of claim 10 further comprising a vent in at least one of the tile frames for cooling the photovoltaic cells.

15. The method of claim 14 further comprising at least three vents in at least one of the tile frames for convection cooling the photovoltaic cells.

16. The method of claim 10 further comprising the use of complementarily formed ends on the first and second tile frames to limit the distance between tile frames.
